(19) United States
(12) Patent Application Publication
(10) Pub. No.: US 2006/0026479 A1
(43) Pub. Date: Feb. 2, 2006

(54) Verification vector creating method, and electronic circuit verifying method using the former method

(76) Inventors: Keijiro Umehara, Uji-shi (JP); Masakazu Tanaka, Kyotanabe-shi (JP)

Correspondence Address: MCDERMOTT WILL & EMERY LLP, 600 13TH STREET, N.W., WASHINGTON, DC, 20005-3096, US

(21) Appl. No.: 11/181,017

(22) Filed: Jul. 14, 2005

(30) Foreign Application Priority Data
Jul. 14, 2004 (JP) P2004-207624

(51) Int. Cl. G06F 11/00; G01R 31/28

(52) U.S. Cl. 714/738

(57) ABSTRACT

To realize an equivalence verification between an analog circuit and its function model unit. From a circuit topology and a functional description, there is extracted contained in the circuit. A test circuit capable of inputting a verification vector according to the extracted circuit function is created, and a verification is made to provide a result. In case the equivalence is to be verified, a similar verification is made by replacing only a compared circuit of the test circuit created. After the result was obtained, its difference from the aforementioned result is made. If this difference is within an allowable range, the equivalence is decided. By using the configuration of the invention, the analog circuit or the function model can be verified on itself. Moreover, the equivalence can be verified with the minimum configuration.

### BACKGROUND OF THE INVENTION

1. Field of the Invention

The present invention relates to a verification vector creating method and an electronic circuit verifying method using the former method. More particularly, the invention relates to a method for verifying a circuit with a verification vector extracted from that circuit and to a method for verifying the equivalence of two or more circuits with the verification vector extracted.

2. Description of the Related Art

In recent years, a circuit to be integrated into an integrated circuit is enlarged in scale so that a large-scale integrated circuit called the “SOC (System On Chip) is developed. This indicates the large-scale integrated circuit, in which a processing system realized in the prior art by a plurality of semiconductor integrated circuits, is integrated into one chip. It is frequent that a circuit (as will be called the “analog-digital mixed circuit”) containing analog circuits and digital circuits mixed therein is integrated in that SOC.

In the prior art, the simulation of the analog circuit has been made by a circuit simulator such as SPICE (Simulation Program with Integrated circuit Emphasis) considering physical properties strictly. In the SPICE, the analog circuit is analyzed by modeling the physical properties of a device formed on silicon strictly to simulate the operations of transistor elements. Generally, however, it takes a long time to execute the circuit simulator. It is, therefore, difficult to simulate the digital circuits and the analog circuits on the common time axis. As a result, the simulation in the combination of the digital circuits and the analog circuits to be mixed and mounted on the SOC is little executed to cause many connection mistakes due to the shortage of verifications.

In order to develop the large-scale circuit such as the SOC for a short period and at a low cost, on the other hand, it is necessary to optimize the system sufficiently at an early stage of the design thereby to decide the specifications for each circuit block. In the field of the digital circuit of the prior art, even the large-scale system can be optimized by making a circuit model using the HDL (Hardware Description Language) thereby to simplify the circuit and to raise the simulation speed. However, the HDL of the prior art finds it difficult to describe the analog circuit and very difficult to optimize the system of the analog-digital mixed circuit.

In these situations, there is developed an analog description language called the AHDL (Analog Hardware Description Language). This language can describe the functions of the analog circuit and has a relatively high simulation speed. Therefore, the AHDL is used for verifying the analog-digital connections and for optimizing the system of the analog-digital mixed SOC.

This AHDL-described model generally expresses the functions of the circuit partially for higher speed simulations so that it fails to express all the characteristics owned by the analog circuits. Therefore, the characteristics modeled with the verification contents executed by that model are diversified. This diversification makes it difficult to create function models automatically, and only the functions requiring the manpower are modeled. In this creation, mistakes are introduced during the works to raise such a problem at all times that the equivalence between the original analog circuits and the function models is not ensured.

In order to solve this problem of equivalence, the analog-digital mixed circuit is configured of a function model in the prior art to store the input from the digital circuits to an analog function mode and to store the output from the analog function model as an expected value. Thus, the equivalence is verified by a method (as referred to JP-A-2000-215222 (pages 1 to 6, FIG. 3), for example) for confirming whether or not the output value at the time when an input signal stored beforehand is given as an input to the analog circuits is equal to the expected value.

FIG. 27 is a schematic flow chart of the aforementioned electronic circuit verifying method of the prior art. Here is described the electronic circuit verifying method of the prior art. In a preprocessing, a functionally described digital circuit DO and a likewise functionally described analog circuit AO are simulated by one function simulator 110 thereby to damp a signal at a boundary between the digital circuit DO and the analog circuit AO. The damped waveform is stored is stored as a function element 130, which can be simulated with an analog circuit 120. An input signal is fed from the function element 130 to the analog circuit 120 so that the equivalence is verified by comparing the signal outputted from the analog circuit and the expected value.

As a method for reducing the connection mistakes between the analog-digital circuits in the SOC, moreover, there is proposed in the prior art a method (as referred to JP-A-2000-323575 (pages 1 to 7, FIG. 5), for example) for confirming whether or not specific operating conditions are satisfied, by confirming the operating conditions of the individual elements of the analog circuit while being fed with an input signal from the digital circuit.

FIG. 28 is a conceptional diagram showing the flows of the aforementioned electronic circuit verifying method of the prior art. Here is described an electronic circuit verifying method of the prior art. At first, analog circuit 210 inputs an input pattern 230 as specific operating conditions to a digital circuit 220, and the logic state of the output value of the digital circuit 220 is stored at 240. It is confirmed whether or not a connection mistake between the analog-digital circuits by confirming what operating state the individual circuit elements of the analog circuit 210 takes when that value is fed to the analog circuit 210. Whether or not all the nodes from a power supply to the ground are blocked is confirmed by deciding, in the specification of the power-down state, for example, whether or not the drains and the sources are blocked by the terminal voltage of a MOS, and by deciding that block unconditionally with a capacitance, if any. Thus, it is possible to discover the connection mistake easily.

### SUMMARY OF THE INVENTION

In the equivalence verifying method and the electronic circuit verifying method thus constituted, however, the signal to be inputted from the digital circuit to the analog circuit is the verification vector so that the equivalence verification between the analog circuit and its function model itself cannot be realized. Intrinsically, the equivalence between the analog circuit and its function model can be verified by themselves and have an unnecessarily large configuration. In case the function model is a general-purpose library, the signal to be inputted to the function model is diversified by the circuits used, so that the equivalence is not warranted in case another input signal is inputted even when it is verified with a specific input signal.

Moreover, the configuration of Patent Publication No. 1 aims at the top-down design method, for which the analog function model is earlier present whereas the analog circuit is later created, but not the bottom-up design method, for which the analog circuit is earlier present whereas the analog function model is later created. The bottom-up design method is employed mainly in the case of performing the connection verification between the analog-digital circuits thereby to raise a problem that the configuration of Patent Publication No. 1 cannot support the connection verification.

The present invention is conceived in view of the background thus far described and has an object to realize a highly reliable circuit verification easily not in dependence upon an input signal.

The invention has another object to realize the equivalence verification between an analog circuit and a function model itself.

The invention has still another object to realize the equivalence verification between a function-described circuit and a layout-described circuit easily.

In order to solve the foregoing problems, a verification vector creating method of the invention is characterized by comprising the step of extracting a circuit verifying vector from an analog circuit or a function model describing the function of the analog circuit with the AHDL. On the other hand, an electronic circuit verifying method of the invention is characterized by comprising: the step of creating a test bench circuit capable of inputting the verifying vector into a circuit to be tested; and the step of verifying the analog circuit and the function model with the test bench circuit and the verification vector thereby to compare the verification results.

The method is characterized by further comprising: the step of analyzing the operating state of analog circuit elements from the verifying vector; and the step of verifying that the analog circuit is in a specific operating condition.

Specifically, the verification vector creating method of the invention is characterized by comprising: the step of extracting the verification vector of the circuit from at least one element circuit of the circuit; and the step of creating the verification vector.

According to this method, the verification vector is extracted by the circuit itself so that a highly reliable verification vector can be easily extracted independently of the input signal or the skills of a verifying designer.

In the verification vector creating method of the invention, moreover, the at least one circuit is an analog circuit.

According to this method, the verification vector can be selected even from the analog circuit, which is difficult to select the verification vector, so that it can be easily extracted.

In the verification vector creating method of the invention, moreover, the at lest one circuit is described by a transistor level description.

According to this method, the verification vector can be easily extracted for the transistor level description.

In the verification vector creating method of the invention, moreover, the at lest one circuit is described by a functional description.

According to this method, the verification vector can be easily extracted even from the functional description circuit.

In the verification vector creating method of the invention, moreover, the creating step includes: the step of extracting a featuring circuit from target circuits; and the step of extracting a vector for verifying the featuring circuit extracted.

According to this method, the featuring circuit is extracted, and the verification vector for this verification is extracted, so that the verification vector can be easily created even for the element circuits included in the circuit. This circuit itself can be verified from the target circuit.

In the verification vector creating method of the invention, moreover, the creating step includes: the step of selecting and scoping an element to be matched, from the circuit; the step of matching a topology at an element level; the step of deciding the verification contents on the element; and the step of creating a verification vector according to the verification contents.

According to this method, the matching is done at the element level so that the element circuit included in the circuit can be extracted and easily verified.

In the verification vector creating method of the invention, moreover, the creating step includes: the step of extracting a featuring circuit from a functional description or a target of the circuit; and the step of extracting a vector for verifying the featuring circuit extracted.

According to this method, the featuring description can be extracted from the functional description so that the verification can be easily made in the functional description.

In the verification vector creating method of the invention, moreover, the creating step includes: the step of extracting a unit description from the circuit; the step of matching the description with the unit description; and the step of deciding the verification contents.

According to this method, the matching is done at the description unit so that the unit description in the functional description can also be easily verified.

In the verification vector creating method of the invention, moreover, the creating step includes: the step of altering the functional description on the circuit into a unit description; the step of matching the description with the unit description; and the step of deciding the verification contents.

According to this method, the matching is done at the description unit so that the unit description in the functional description can also be easily verified.

In the verification vector creating method of the invention, moreover, the creating step creates, on the basis of corresponding information between circuit features prepared beforehand and the verification vector, the verification vector for the circuit features extracted by the step of extracting the featuring circuit.

According to this method, the verification vector can be easily created for the circuit features extracted.

In the verification vector creating method of the invention, moreover, the creating step creates the verification vector on the basis of the corresponding information among the description feature extracted by the step of extracting a featuring description, a prepared description feature and the verification vector.

According to this method, the verification vector can be easily created for the circuit features extracted.

In the verification vector creating method of the invention, moreover, the at least one circuit is layout-described.

According to this method, the verification vector can be easily created for the layout description.

In the verification vector creating method of the invention, moreover, the creating step includes the step of extracting the transistor level description of the circuit from the layout.

According to this method, the verification vector can be easily created for the layout description like the transistor level description.

In the verification vector creating method of the invention, moreover, the transistor level description of the circuit extracted from the layout contains parasitic element information.

According to this method, the verification vector can be easily created even if the parasitic element information is contained in the transistor description extracted from the layout.

In the verification vector creating method of the invention, moreover, the functional description is at least one of Verilog-A and Verilog-AMS descriptions.

According to this method, the standard languages Verilog-A and Verilog-AMS of the analog function description can be easily verified.

In the verification vector creating method of the invention, moreover, the featuring circuit means a switch.

According to this method, the verification vector can be easily created for the switch circuit.

In the verification vector creating method of the invention, moreover, the featuring description means a switch.

According to this method, the verification vector ca n be easily created for the layout description of the switch circuit.

The circuit verifying method of the invention comprises: the step of creating, by using the verification vector created by the aforementioned verification vector creating method, the verification vector of at least one circuit of target circuits; and the step of verifying the circuit with the verification vector extracted.

According to this method, the circuit can be easily verified independently of the input signal or the skills of a verifying designer.

In the circuit verifying method of the invention, moreover, the verifying step includes the step of verifying whether or not at least two circuits are functionally equivalent.

According to this method, it is possible to easily verify the equivalence between the two or more circuits. It is also possible to easily perform the equivalence verification of the two or more circuits no matter what kind of the circuit expression or combination the transistor level circuit, the functional description circuit or the layout description circuit might be.

In the circuit verifying method of the invention, moreover, the extracting step includes the step of extracting the transistor level description of the circuit from a layout description, and the verifying step includes a circuit verifying step using the verification vector obtained from the transistor level description of the circuit.

According to this method, the circuit verification at the level equivalent to the circuit diagram can be easily made from the layout description.

In the circuit verifying method of the invention, moreover, the transistor level description of the circuit extracted from the layout description contains parasitic information.

According to this method, the circuit verification can be made highly precisely even if the parasitic element information is contained.

Moreover, it is desired that the circuit verifying method includes the step of verifying the transistor level description of the circuit obtained at the extracting step by using the transistor level description of the circuit extracted from the layout description.

According to this method, the equivalence verification between the circuit diagram and the layout can be easily performed.

In the circuit verifying method of the invention, moreover, the creating step includes: the step of extracting an input condition for the circuit to come into a specific state; and the step of extracting a verification vector for the circuit to come into the specific state, from the input condition.

According to this method, the operation in the specific state can be easily verified.

In the circuit verifying method of the invention, moreover, the at least one circuit is functionally described, and wherein the method comprises the step of verifying the circuit.

According to this method, the circuit verification can be easily made for the functionally described circuit.

In the circuit verifying method of the invention, moreover, the verifying step includes the step of comparing the verification results at the verifying step and deciding the result on whether or not the characteristics or functions are equivalent to specifications.

According to this method, it is possible to easily verify whether or not the characteristics or the functions are equivalent to the specifications.

In the circuit verifying method of the invention, moreover, the decision of the results at the deciding step is based on whether or not the circuit is in the specific state.

According to this method, it is possible to easily verify whether or not the circuit is in the specific state.

In the circuit verifying method of the invention, the verifying step includes: the step of creating a combination of input signals; and the step of deciding whether or not the circuit is in the specific state.

According to this method, it is possible to easily verify what case the specific state is established in.

In the circuit verifying method of the invention, moreover, the specific state is a power-down state.

According to this method, the power-down state can be easily verified.

In the circuit verifying method of the invention, moreover, the verifying step includes the step of creating a test circuit with the verification vector created at the extracting step and the circuit information extracted by the feature extracting means.

According to this method, the test circuit can be easily created from the circuit information, and the circuit verification can be easily performed.

In the circuit verifying method of the invention, moreover, the verifying step includes the step of creating a test circuit with the verification vector created at the extracting step and the description information extracted by the feature extracting means.

According to this method, the test circuit can be easily created from the description information, and the circuit verification can be easily performed.

According to verification vector creating method of the invention, the verification vector is created from the circuit itself so that the verification vector can be easily created independently of the input signal or the skills of the verifying designer. No matter what the expression means of the target circuit for creating the verification vector might be, moreover, the verification vector can be created even with the transistor level description, the functional description and the layout description.

According to the electronic circuit verifying method of the invention, moreover, the circuit itself can be verified with the analog circuit or the function model itself. By using this verification vector, the analog circuit or the function model can be verified with the minimum configuration. By using the circuit verification environment created, moreover, it is possible to verify the equivalence of two or more circuits. Any combination of the targets of the equivalence verification can be verified no matter what the circuit expression method might be. Moreover, the equivalence can be verified between the analog circuits and between the function models. Moreover, this equivalence verifying method can also be used even in the bottom-up design method, in which the analog circuit is earlier present whereas the function model is later created. By using the verification vector of the invention, moreover, it is possible to verify with the minimum configuration that the analog circuit is under a specific operating condition.

### BRIEF DESCRIPTION OF THE DRAWINGS

FIG. 1 is a flow chart of an electronic circuit verifying method in Embodiment 1 of the invention;

FIG. 2 is a detailed flow chart of a feature extraction .(302);

FIG. 3 is one example of a topology searching rule;

FIG. 4 is one example of a transistor level description to be inputted;

FIG. 5 is one example of specified verification contents;

FIG. 6 is a detailed flow chart of the feature extraction (302) of Embodiment 2 of the invention;

FIG. 7 is an example of a circuit of a functional description to be inputted;

FIG. 8 is one example of a description searching rule;

FIG. 9 is one example of a circuit diagram of a functional description;

FIG. 10 is one example of verification contents;

FIG. 11 is a detailed flow chart of the feature extraction (302) of Embodiment 3 of the invention;

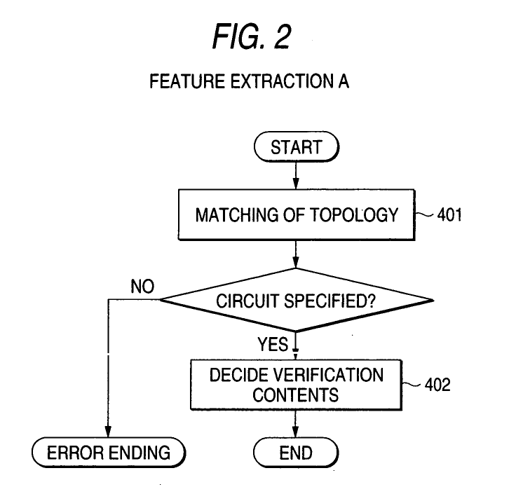

FIG. 2 is one example of a layout rule;

FIG. 13 is one example of a layout to be inputted;

FIG. 14 is one example of a transistor level description extracted from the layout;

FIG. 15 is a detailed flow chart of the feature extraction;

FIG. 16 is one example of a circuit of a transistor level description to be inputted in Embodiment 4 of the invention;

FIG. 17 is one example of a circuit of a functional description to be inputted in Embodiment 5 of the invention;

FIG. 18 is a detailed flow chart of the feature extraction (302);

FIG. 19 is one example of a description searching rule for each unit description;

FIG. 20 is a flow chart of an electronic circuit verifying method in Embodiment 6 of the invention;

FIG. 21 is a flow chart of an electronic circuit verifying method in Embodiment 7 of the invention;

FIG. 22 is a detailed flow chart for deciding whether or not the state decision (2304) of the circuit of FIG. 21 is in a power-down state;

FIG. 23 is a flow chart for a verification vector creation;

FIG. 24 is one example of information intrinsic to the circuit;

FIG. 25 is one example of a verification vector;

FIG. 26 is one example of a test circuit;

FIG. 27 is a schematic flow chart diagram of the electronic circuit verifying method of the prior art; and

FIG. 28 is a conceptional diagram showing the flows of the electronic circuit verifying method of the prior art.

### DESCRIPTION OF THE PREFERRED EMBODIMENTS

Embodiments of the invention will be described with reference to the accompanying drawings.

(Embodiment 1)

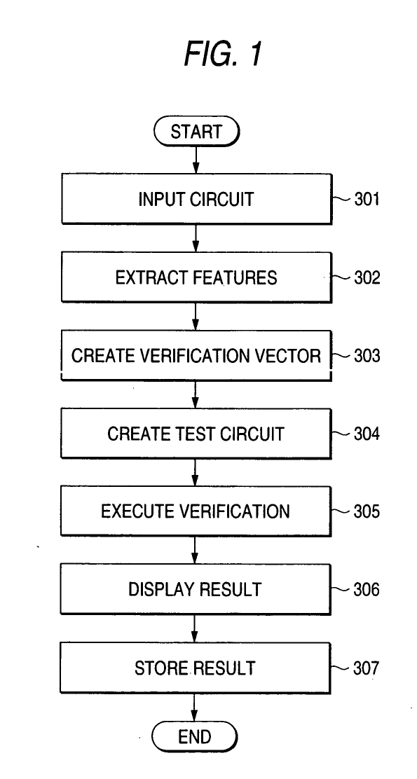

FIG. 1 is a flow chart showing an electronic circuit verifying method of the invention. In this embodiment, it is assumed that a SPICE net list is inputted as one example of the transistor level description. This embodiment is characterized in that a featuring circuit is extracted from target circuits inputted with a transistor level description, thereby to extract a vector for verifying the featuring circuit extracted.

At first, when a circuit to be verified is inputted, its format is decided (at 301). In this embodiment, the SPICE net list of the transistor level description is inputted so that the transistor level description is decided.

Thus, the circuit having the format decided is inputted to a step of extracting a featuring circuit, i.e., a feature extracting step (at 302).

A detailed flow chart of the feature extracting step of the case, in which the inputted circuit is the transistor level description, is shown in FIG. 2.

It is matched (at 401) whether or not the inputted SPICE net list is the same topology as that described in the rule.

When it is decided whether or not the circuit specification has been done so that the circuit function is specified by the matching of the topology, the verification contents are decided (at 402) by selecting a verification item predetermined on a circuit function.

In case the circuit is not specified, the processing flow is ended as an error.

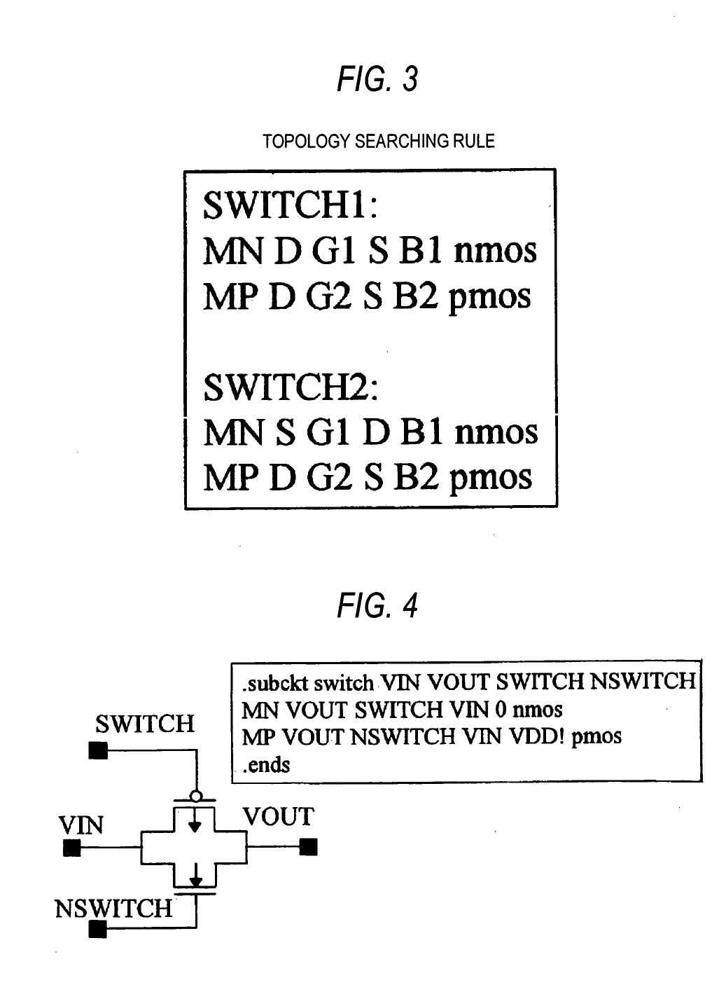

FIG. 3 shows an example of a rule file to be used in the topology matching (at 401) of FIG. 2. This rule exemplifies the topology matching rule of an analog switch circuit shown in FIG. 4. This analog switch circuit is configured by connecting the drains or sources of paired PMOS and NMOS with each other. Therefore, the rule is described to decide the analog switch, if the drains or the sources are given the same net name and if the gates and the back gates are given different net names.

Here, the connection information of the circuit is also extracted at the topology matching time. Specifically, there are extracted the net name indicated in the rule file and the mapping information of the net name actually used in the circuit having a specified circuit function.

In FIG. 3 and FIG. 4, for example, there is extracted the connection information that the nets D, S, G1, G2, B1 and B2 of FIG. 3 are mapped to the nets VOUT, VIN, SWITCH, NSWITCH, 0 and VDD! of FIG. 4, respectively.

When the circuit function is decided at the feature extraction (of 302), the verification vector is created (at 303).

FIG. 23 summarizes the verification vector creation (of 303) into a flow chart.

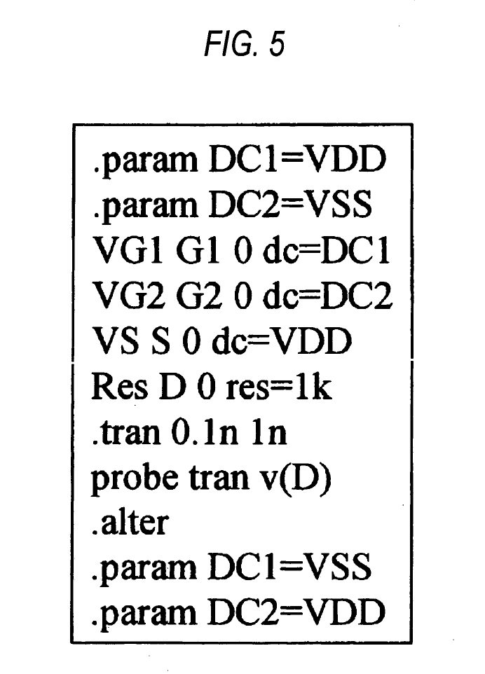

At first, when the verification contents are decided (at 402), the specified verification contents predetermined on the circuit function are selected (at 2501). An example of the specified verification contents of the circuit decided as the analog switch is shown in FIG. 5. These are the contents for verifying the conditions for the switch to be turned ON, and it is possible to decide that the conditions for the high VD voltage are ON. The verification vector is created (at 2503) by adding the information (of 2502) designated beforehand, as the intrinsic information of the target circuit to the verification contents. An example of the intrinsic information of the target circuit designated beforehand is shown in FIG. 24.

This information is given from the process, and the value of the supply voltage, the temperature condition, the model parameters and so on are defined in this example. An example of the verification vector created is shown in FIG. 25. FIG. 25 is constituted by combining FIG. 5 and FIG. 24. Thus, it is possible to create the verification vector according to the process or the verification condition.

A test circuit is created (at 304) by combining the verification vector created at the verification vector creating step (303) and a circuit diagram inputted. An example of the test circuit created is shown in FIG. 26. This test circuit is created by combining the inputted circuit (FIG. 4) A, the verification vector (FIG. 25) B and the connection information C extracted at the feature extracting step (302).

In case a plurality of circuit functions are discovered at the feature extracting step, a plurality of test circuits may be created. Finally: a simulation is executed (at 305) on the test circuit; the result is displayed (at 306); the result is stored (at 307); and the routine is ended.

This embodiment is enabled to specify the circuit function automatically on the inputted circuit, to create the according test bench circuit thereby to execute the verification, and to display the result. As a result, the embodiment can reduce the number of steps for the verification. Moreover, the embodiment can also realize the circuit verification on the common standards independent of the skills of the designer.

In this embodiment, the SPICE net list is inputted as one example of the transistor level description, but a circuit diagram may also be inputted as an example of the functional description. This case can be handled like the case of inputting the SPICE net list of this embodiment by providing a step of extracting the net list from the circuit diagram.

(Embodiment 2)

Embodiment 1 has been described supposing the case, in which the SPICE net list is inputted in FIG. 1. However, this embodiment is described on a flow of the case, in which the functional description is inputted.

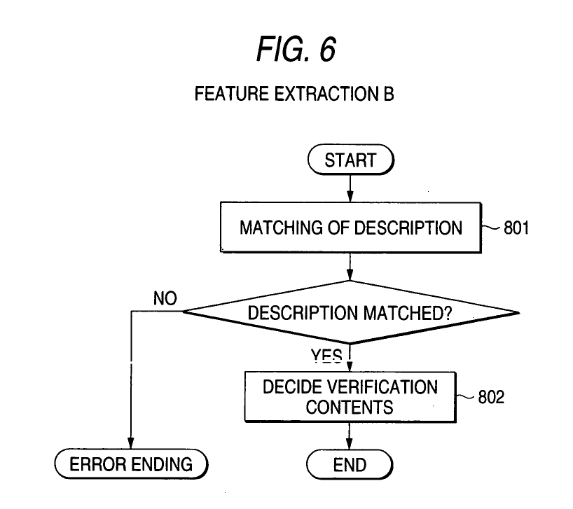

A detailed flow chart of the feature extraction (of 302) of the case, in which the functional description is inputted, is shown in FIG. 6.

The inputted functional description is searched for the description, and a matching is carried out (at 801) to search whether or not the description is written in the rule. If the circuit function is specified by the description matching (of 801), the verification contents are decided (at 802) by selecting a verification item for the circuit function.

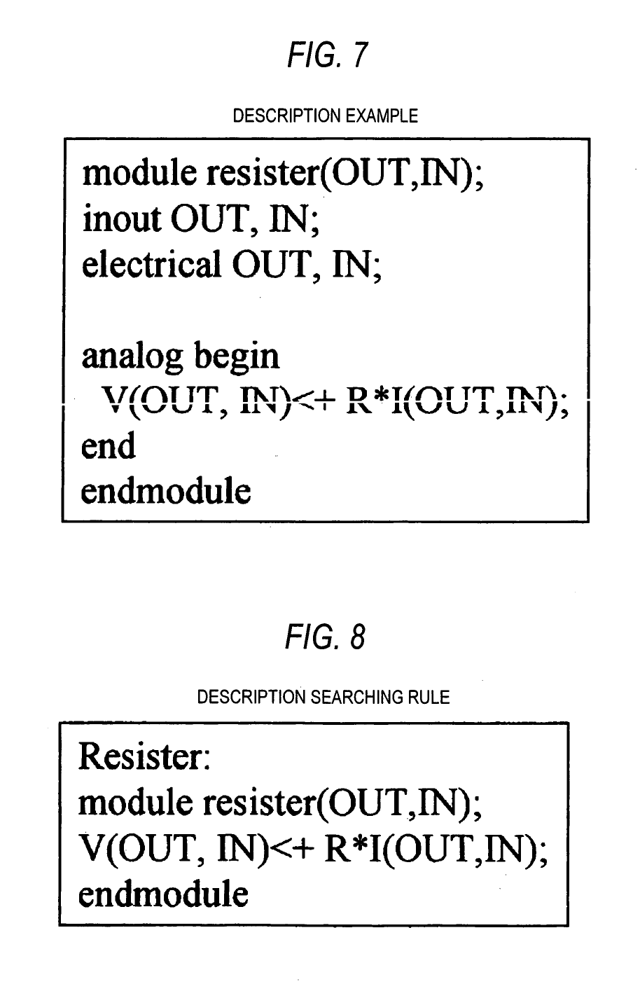

FIG. 7 shows a description example of the inputted functional description. This module is a description example of a resistor. The description language used in this example is Verilog-A or Verilog-AMS but may also be Verilog-HDL, VHDL, VHDL-A, VHDL-AMS, SystemVerilog, System VHDL, C, C++, SystemC or Matlab.

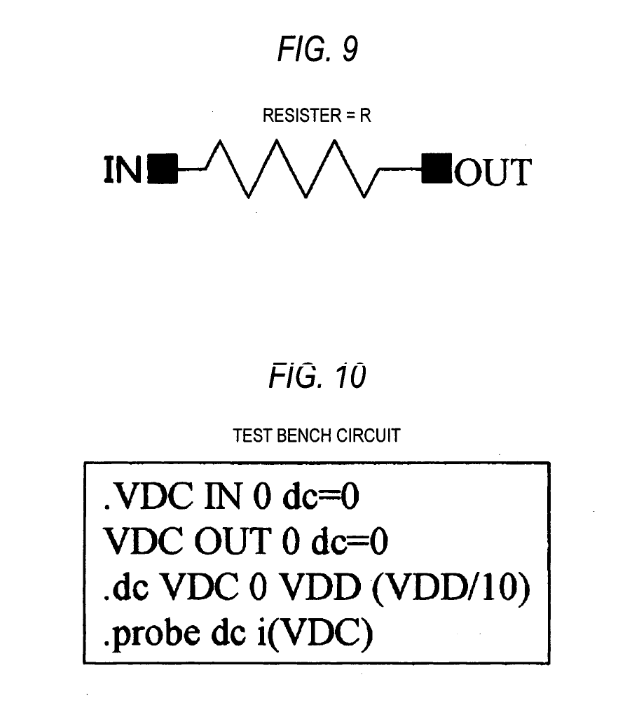

FIG. 8 shows an example of the rule file which is used in the description matching (of 801). This rule shows an example of the description matching rule of a resistor shown in FIG. 9.

When the circuit function of the circuit inputted at the description matching step 801 of FIG. 6 is specified, the verification contents predetermined on the circuit function are selected. An example of the verification contents of the circuit decided as the resistor is shown in FIG. 10. In the contents, the voltage at the other end of the resistor is raised to verify whether or not the current increases with the resistance. As a result, it is possible to decide 21. whether or not the resistor normally acts.

The processing at and after the creation of the verification vector (at 303) of FIG. 1 is similar to that of Embodiment 1.

(Embodiment 3)

With reference to FIG. 1, Embodiment 1 has been described supposing the case, in which the SPICE net list is inputted, and Embodiment 2 has been described supposing the case, in which the function model is inputted. This embodiment is described on the flow of the case, in which layout data are inputted.

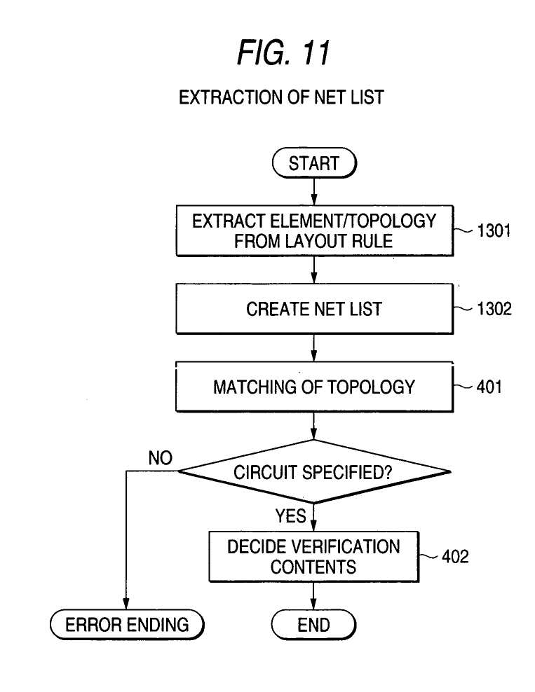

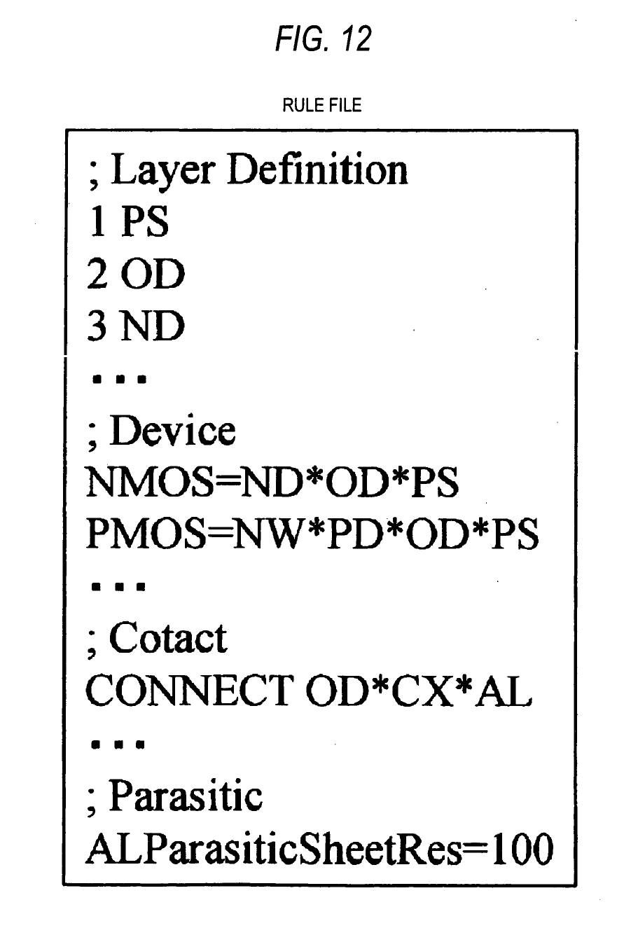

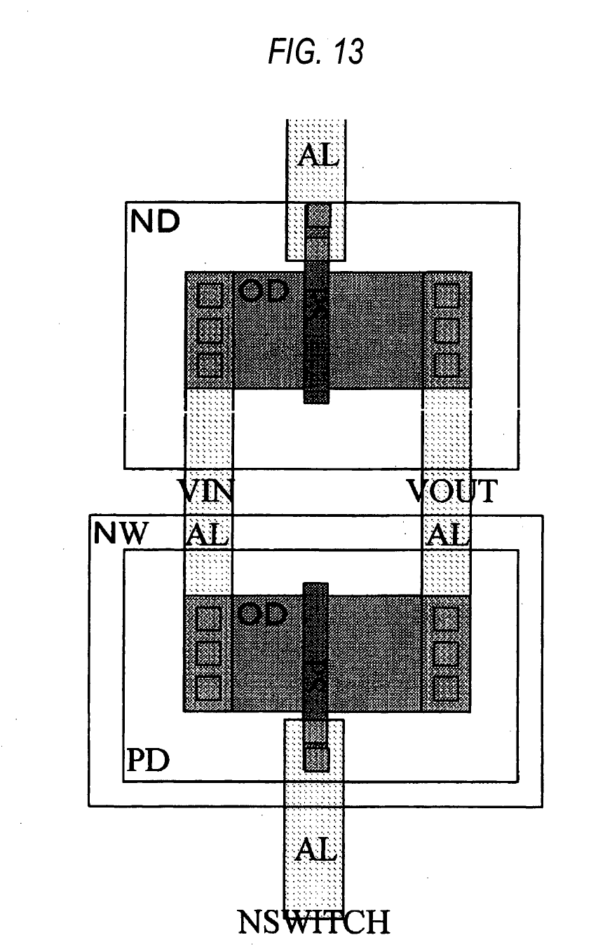

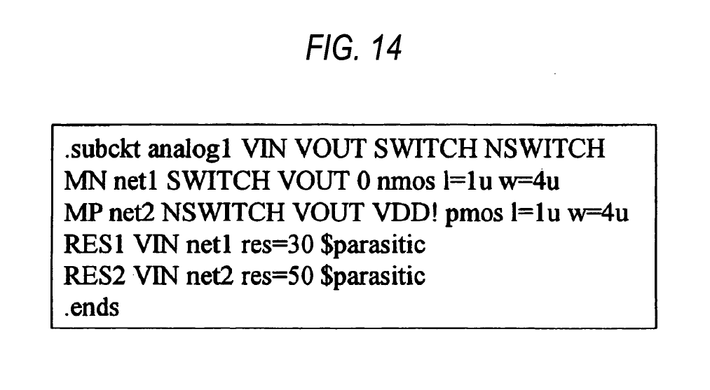

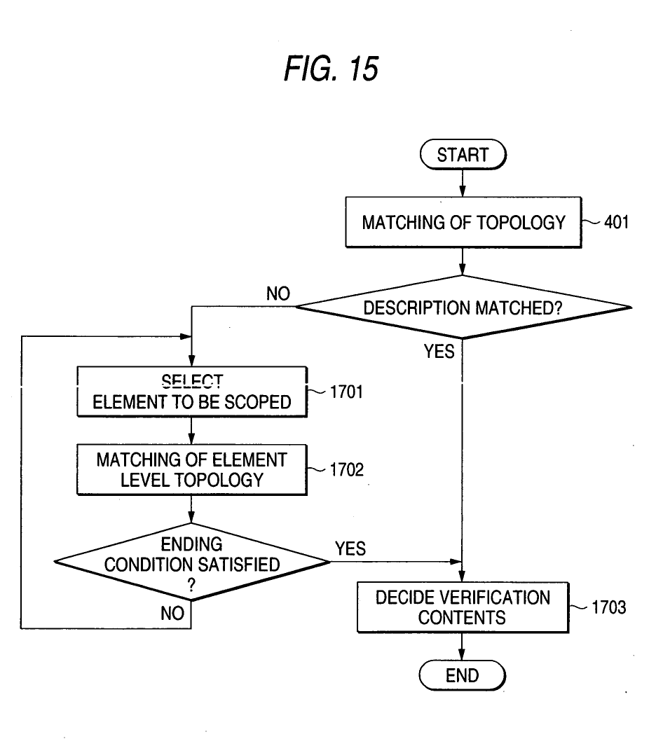

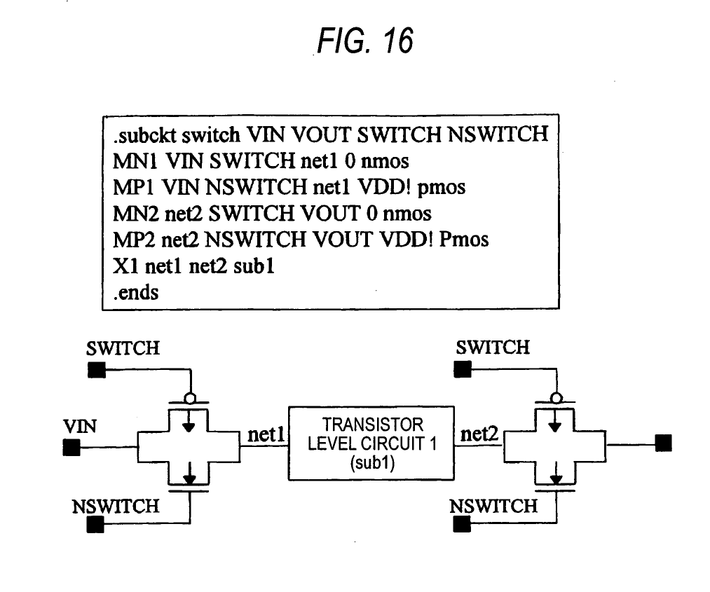

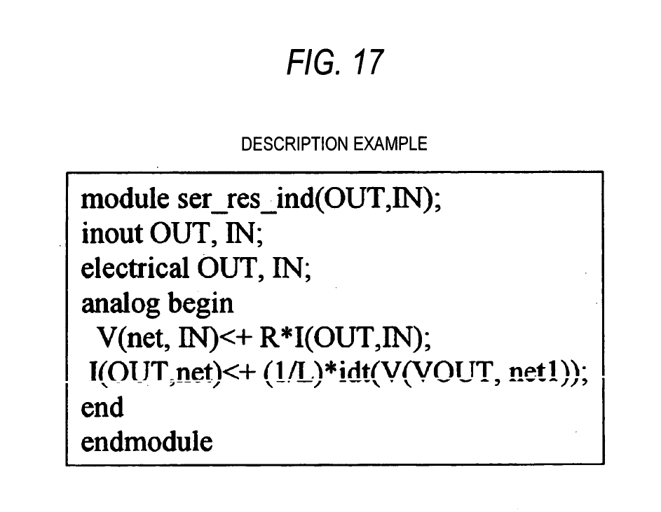

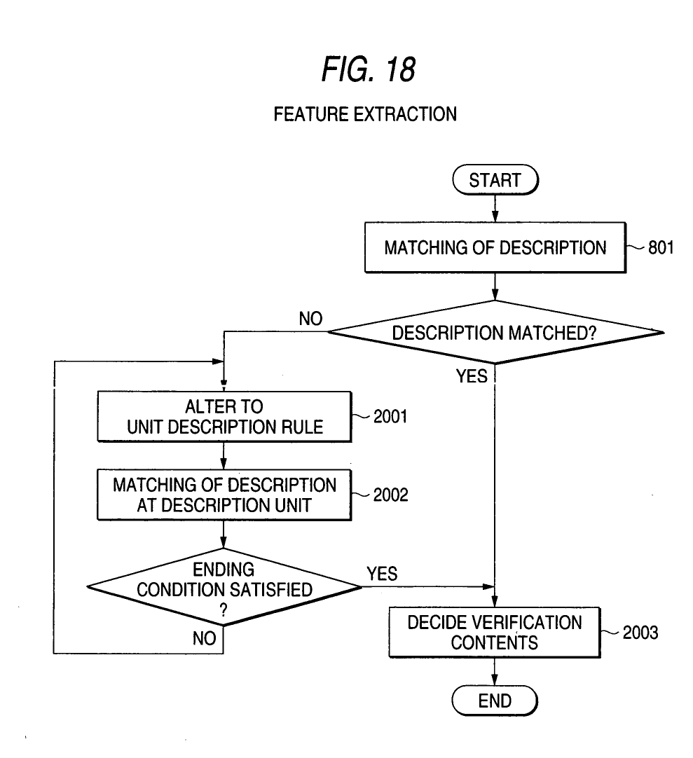

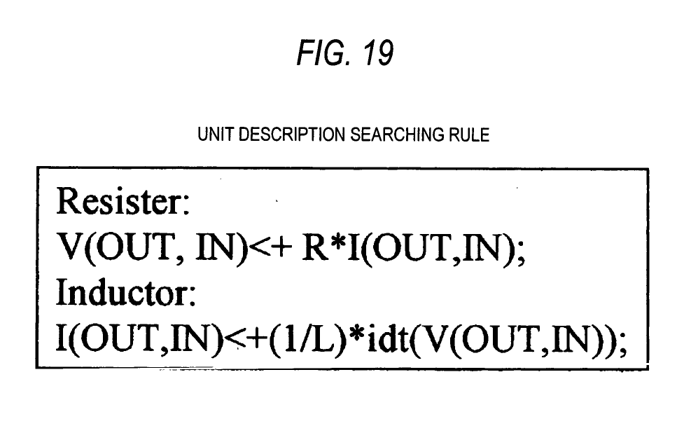

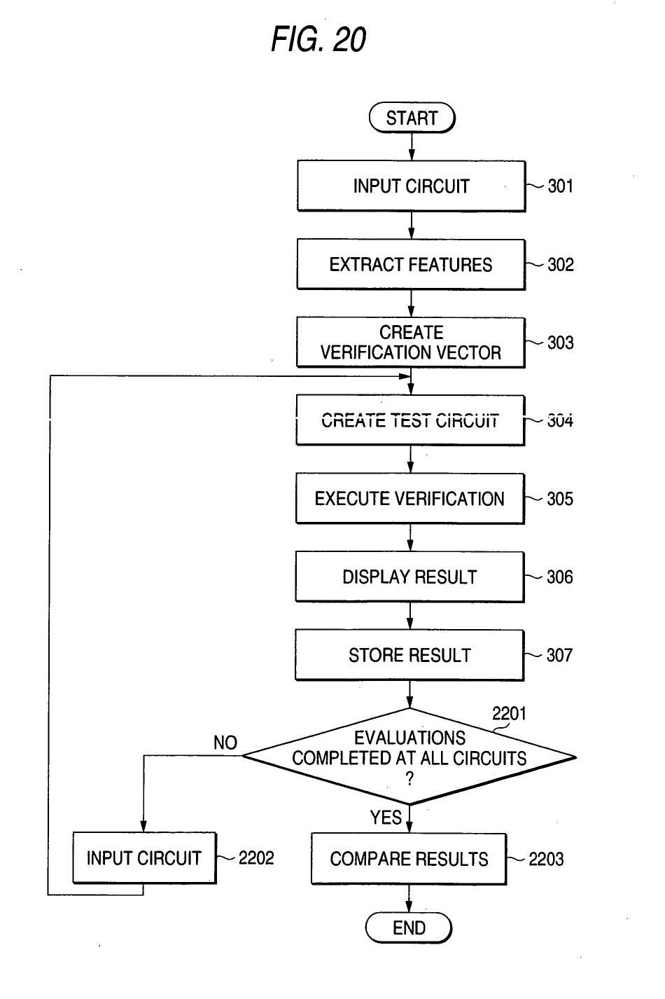

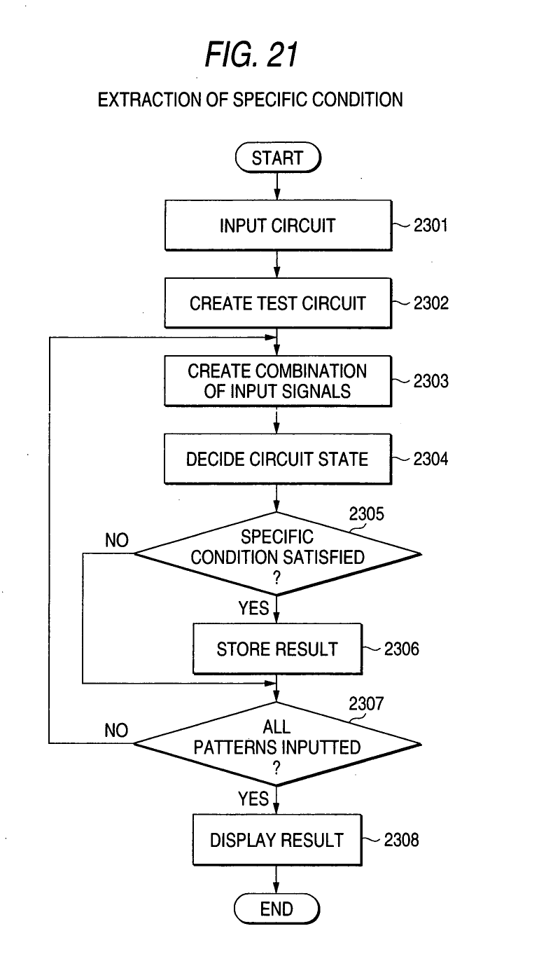

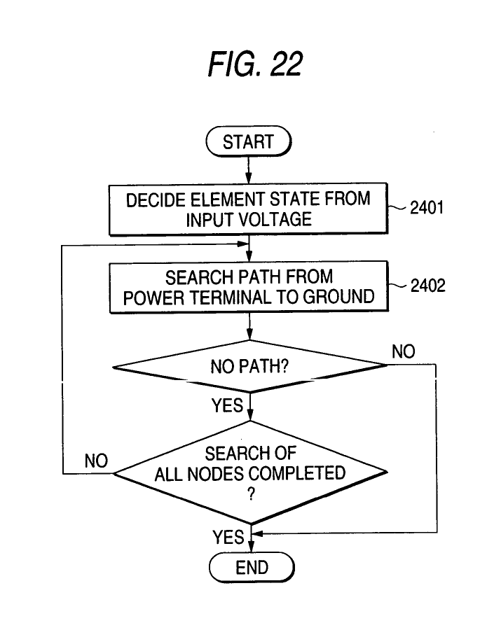

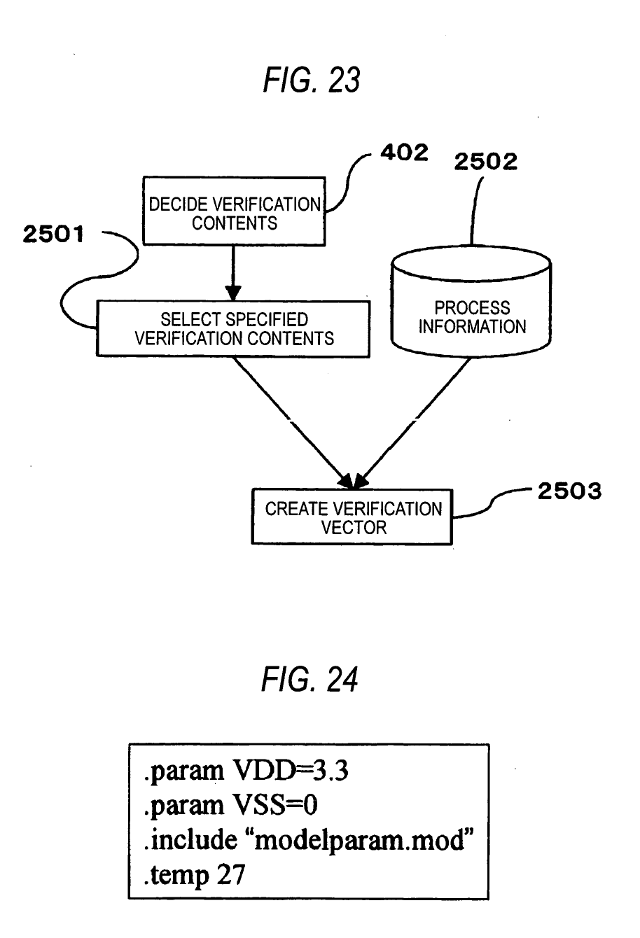

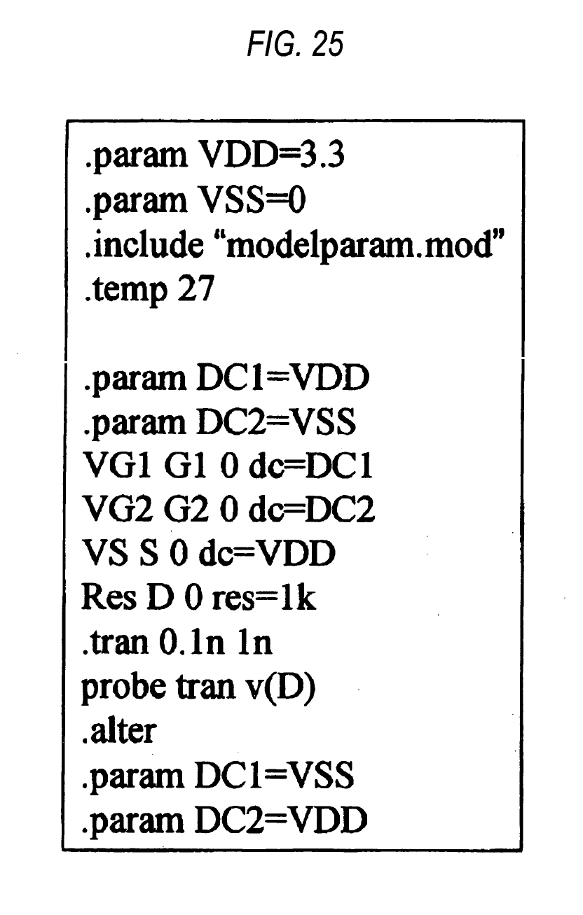

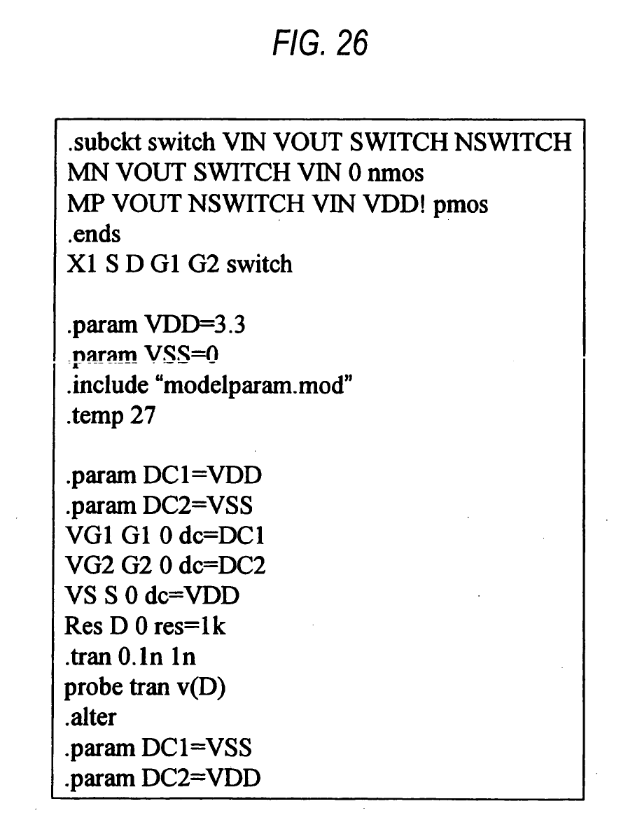

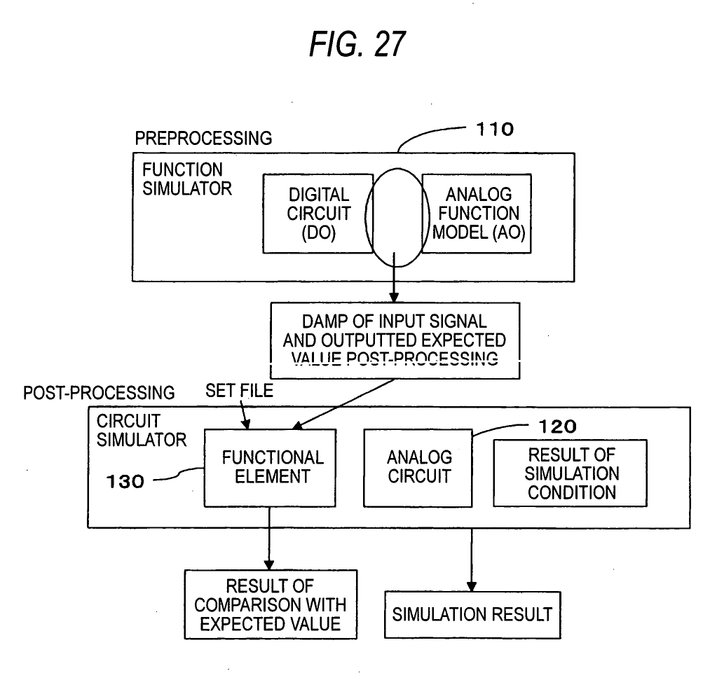

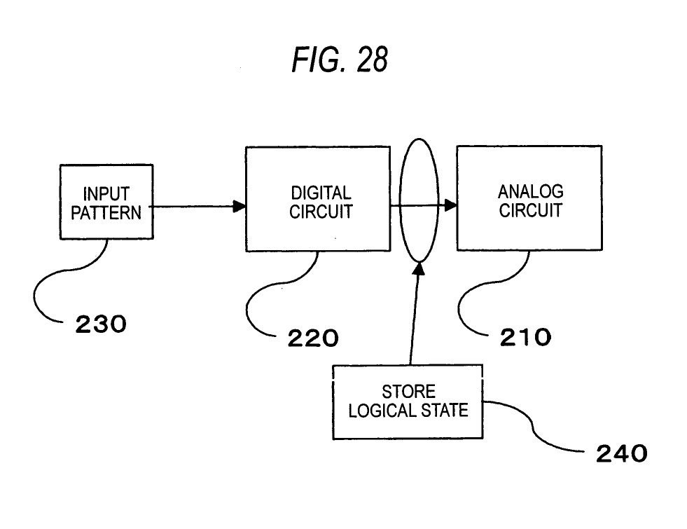

A detailed flow chart of the feature extraction step (302) of the case, in which the layout data are inputted, is shown in FIG. 11.

On the basis of the layout data inputted, an element or a topology is extracted from the layout rule (at 1301). FIG. 12 shows the layout rule at the time when the element or topology is extracted. This rule is composed of the definition of a layer name, the operation expression of a layer for recognizing a device, an equation for calculating the size of the device, a contact rule for a wiring between layers, an extraction rule of a parasitic element and so on. The element or the connection of each layer can be recognized by a graphic data processing using that rule.

The element/topology extracted is outputted (at 1302) as the net list of a transistor level description, for example. In case the net list used relates to the net having a label set in the wiring layer of the layout, the net list having the label name is outputted and registered as input/output pins.

If the mask layout of an analog switch circuit shown in FIG. 13 is inputted to the electronic circuit verifying method of this embodiment, for example, the element and the topology are extracted from the layout rule. This extraction result is outputted in the form of the example of the SPICE net list, as shown in FIG. 14.

The net list of the transistor level description outputted is processed like the feature extraction flow chart at the time when the transistor level description of FIG. 2 is inputted. The subsequent processing is similar to that of Embodiment 1.

If, moreover, not only the connection relation of the elements but also the net list of the transistor level including the parasitic elements is extracted from the layout by an LPE (Layout Parasitic Extraction) method or the like, the characteristics of the circuit including the parasitic elements can be verified. If the parasitic elements are not taken into consideration, on the contrary, the verification of only the element and the topology can be performed at a high speed.

(Embodiment 4)

With reference to FIG. 1, Embodiment 1 has been described on the operations of the case, in which the SPICE net list is inputted as one example of the description of the transistor level. Embodiment 1 has been unable to perform the matching of the topology, in case the inputted circuit is a combination of a plurality of circuit functions, as shown in FIG. 16.

In order to solve this problem, this embodiment partially extracts a circuit having features described in the matching rule of topology, from a circuit having a plurality of circuits combined, and verifies the extracted circuit, as described in the following.

A flow chart of this embodiment on the feature extraction step (of 302) shown in FIG. 1 is shown in FIG. 15. The operations of the electronic circuit verifying method of this embodiment are described supposing that the circuit shown in FIG. 16 is inputted.

This circuit is subjected to the feature extraction by using the topology searching rule shown in FIG. 3. At first, the matching is made (at 401) on whether or not the inputted circuit has a topology identical to that described in the topology searching rule.

Here is no matching rule, and the search is made where the portion of the inputted circuit matches the rule. At first, one element contained in the rule is selected from the circuit and is scoped (at 1701). An element to be matched by the rule is searched (at 1702) according to the standard of that element. The circuit to match the rule is stored if it is discovered by the topology matching at the element level.

For example, an MN1 of a circuit of FIG. 16 is scoped to search an element conforming to the rule (at 1702). In this rule, an element having a source or drain terminal connected with the source or drain terminal of the pMOS may be searched for the MN1. As a result, an MP1 is hit and decided to match the rule. The circuit function expressed by the matching rule and the information of the element are stored.

The search of MN1 is finished, but the ending condition is not satisfied. Next, MN2 is selected as an element contained in the rule and is scoped (at 1701) to search an element applicable to the rule (at 1702). As a result, an MP2 is hit and decided to match the rule.

This processing is executed till the ending condition is satisfied. The ending condition is exemplified by the scope of all elements, the loop of a predetermined number, a finding of a first matching circuit, a finding of the designated number of matching circuits, and these conditions are decided beforehand.

From the circuit function and the element information discovered, the predetermined verification contents are selected (at 1703).

The subsequent processing is similar to that of Embodiment 1.

(Embodiment 5)

In FIG. 1, Embodiment 2 has been described on the operations of the case, in which the functional description is inputted. In Embodiment 2, the description cannot be matched in case the inputted circuit is one having a plurality of descriptions combined, as shown in FIG. 17.

In order to solve this problem, this embodiment will be described on the method, by which a description having features described in the matching rule of the description is partially extracted from the circuit having the plural descriptions combined and is subjected to the circuit verification.

A flow chart of the feature extracting step (302) in this embodiment is shown in FIG. 18. The operations are described assuming that a circuit shown in FIG. 17 is inputted to the electronic circuit verifying method of this embodiment.

The feature extraction is performed on this circuit by using the searching rule of the description shown in FIG. 8, i.e., the functional description. It is matched (at 401) at first whether or not the circuit inputted is identical to that described in the rule.

Here is no matching rule, and the portion where a portion of the inputted circuit matches the rule is searched. At first, the description searching rule is altered (at 2001) to a rule for the search in a unit description, as shown in FIG. 19. The unit description designates the description of the syllable-divided letters in the functional description. The syllable-divided letters are “;” (semicolon) in Verilog-A.

Next, the description matching the rule is searched at each unit description of the inputted functional descriptions. Here, the description is stored if it matches the rule. If the description is searched by using the searching rule at the unit description shown in FIG. 19 for the circuit of FIG. 17, the fifth line matches the rule, and the matching description and the circuit function of the rule are stored. When the matching is ended for all the unit descriptions, the search is performed by altering the rule to a next one.

This processing is executed till the ending condition is satisfied. The ending condition is exemplified by the search with all rules, the loop of a predetermined number, a finding of a first matching circuit, a finding of the designated number of matching circuits.

From the circuit function and the description information discovered, the predetermined verification contents are selected (at 2003).

The subsequent processing is similar to that of Embodiment 1.

(Embodiment 6)

FIG. 20 is a flow chart summarizing a verifying method for comparing the results of two or more circuits with the same verification vectors in the electronic circuit verifying method of the invention.

The operations 301 to 307 of FIG. 20 are similar to those of Embodiments 1 to 5 (as referred to FIG. 3). Here: the test vector is created (at 303) for the inputted circuit; the test circuit is created (at 304); and the results are stored (at 307).

Next, in case another circuit is to be verified with the same test vector, the answer of the condition decision of 2201 is No, and another circuit to be verified is inputted (at 2202). In order that the same test vector as has been created for the inputted circuit at 303 may be inputted to another circuit, a test circuit is created (at 304). At this time, another circuit to be inputted is so conditioned that the net name, to which at least the test vector is inputted, is identical to that of the circuit inputted beforehand.

The verification is executed (at 305) on the created test circuit, and the results are stored (at 307). In case the verification is to be executed by inputting still another circuit, the answer of the condition decision of 2201 is No, and the verification is executed again.

When the verification is thus ended on all circuits, the verification results in the individual circuits are compared (at 2203). These comparisons are made with the ratio of the mean square errors or differences between the waveforms, the value of a control signal for turning ON the switch, the difference (e.g., the voltage value at a time) of the values at the points of the waveforms, and so on.

If the errors are within an allowable range defined beforehand at this step, it is decided that the results are identical. Thus, it is possible to verify the equivalence between the original circuit and the circuit verified with the same test vector.

In this equivalence verification, the transistor level and the functional description can be verified without any problem by any combination of the formats of the circuits to be compared, and the equivalent verification can be made between the circuits of the transistor level description and between the circuits of the functional description.

At the comparing time, moreover, any format of the circuit of the basis for comparison raises no problem so that the circuit inputted at first establishes a basis for the comparison. In case, therefore, a function model and an analog circuit are to be verified on their equivalence when the function model exists earlier at the time of a top-down design and when the analog circuit is designed later, the functional description may be first inputted as the circuit for the basis of comparison.

In case, on the contrary, the analog circuit exists before and is followed by the creation of the functional description when the bottom-up design is made, the analog circuit may be first inputted as the circuit for the comparison basis. Thus, the equivalence verifying method of this embodiment can correspond to both the top-down and the bottom-up design methods.

According to the invention, moreover, it is possible to verify whether or not the circuit characteristics after the layout are equivalent to the characteristics at the transistor level or the function level. Moreover, in case the layout correction is made, it is possible to verify the equivalence of the characteristics before and after the layout correction.

(Embodiment 7)

FIG. 21 shows a flow chart of a method in the electronic circuit verifying method of the invention, for extracting a condition for the circuit to take a specific state.

According to this verification flow, as shown in FIG. 21, when a circuit having its input terminals designated is inputted (at 2301), a test circuit capable of inputting the verification vector to the input terminals is created (at 2302) to create a combination of the verification vectors to be inputted to the circuit (at 2303). The operation states of individual elements for the test circuit, to which the created verification vectors are inputted, are decided (at 2304) to verify (at 2305) whether or not the inputted circuit is in a specific state.

If the specific state is established, the results are stored (at 2306). Then, the patterns of the verification vector are sequentially inputted to decide (at 2307) whether or not the verifications of all the combinations to be taken by the inputted verification vector are completed. If not completed, the routine returns to 2303, at which the verification is repeated. If the verifications of all the combinations taken by the inputted verification vector are completed, the routine is ended by displaying the input vector, for which the inputted circuit takes the specific state, is displayed (at 2308).

Next, this embodiment is described on the flow of the case for extracting the input signal condition, in which the specific state of the circuit to be extracted is in the power-down state. The voltage of the verification vector applies two voltages, at which the elements included in the circuit are turned ON or broken. It is assumed, for example, that the supply voltage of the inputted circuit and the ground voltage are applied. The verification vector is given as a combination of the two voltages to all the input terminals.

At first, when the circuit having its input terminals, power terminals and ground terminals designated is inputted (at 2301), there is created (at 2302) the test circuit which can apply the supply voltage valve or the ground voltage to the input terminals. The verification vector to be inputted to the circuit is constituted (at 2303) in combination of two values of the supply voltage and the ground voltage for the input terminals. The operating states of the individual elements are decided for the test circuit, to which the created verification vector is inputted, and it is verified (at 2304) whether or not the inputted circuit is in the power-down state.

FIG. 22 is a diagram showing a flow chart with a step of deciding the power-down state. At first, the operation states of the individual elements of the inputted circuit are decided (at 2401) with the value of the verification vector of the test circuit. In case the power-down is decided, it is decided whether or not the transistor is ON.

Next: the ON transistor is decided to have its drain terminal and source terminal connected; the OFF transistor is decided to have a topology connected between the drain terminal and the source terminal; and the capacitor is decided to be always OFF. The topology is searched from the node designated as the power terminal, and all nodes are searched (at 2402) on the presence of a node connected with the ground.

At this time, if no node connected with the ground is found, the remaining power terminals are subjected to a similar processing. Even if this processing on all the power terminals cannot find the node connected with the ground, the verification vector is decided to be in the power-down state and is stored (at 2306). If a node connected with the ground is discovered, the processing is then interrupted. All the verification vectors are likewise processed, and the routine is ended (at 2308) by displaying the conditions for the verification vector decided as the power-down. This result display is made understandable with a simplification of input logic by setting the value of the terminal having inputted the supply voltage to 1 and the value of the terminal having inputted the ground voltage to 0.

Thus, the power-down condition can be extracted from the inputted circuit, and the logical error of the control signal of the circuit can be reduced by confirming whether or not the extracted result conforms to the specifications.

The electronic circuit verifying method according to the invention has the step of extracting the circuit verifying vector from the circuit to be verified, and is useful for verifying the equivalence between the function mode and the analog circuit at the SOC designing time. The method is also useful for confirming a specific operating condition or the like.

What is claimed is:

1. A method for creating a vector to verify a circuit, comprising: the steps of:
extracting the verification vector of the circuit from at least one element circuit of the circuit; and
creating the verification vector.

2. The verification vector creating method according to claim 1, wherein the at least one circuit is an analog circuit.

3. The verification vector creating method according to claim 1 or 2, wherein the at lest one circuit is described by a transistor level description.

4. The verification vector creating method according to claim 1 or 2, wherein the at lest one circuit is described by a functional description.

5. The verification vector creating method according to any of claims 1 to 4, wherein the creating step includes the steps of:
extracting a featuring circuit from target circuits; and
extracting a vector for verifying the featuring circuit extracted.

6. The verification vector creating method as set forth claim 1, wherein the creating step includes the steps of:
selecting and scoping an element to be matched, from the circuit;
matching a topology at elements level; the step of deciding the verification contents on the element; and
creating a verification vector according to the verification contents.

7. The verification vector creating method according to claim 4, wherein the creating step includes the steps of:
extracting a featuring circuit from a functional description or a target of the circuit; and
extracting a vector for verifying the featuring circuit extracted.

8. The verification vector creating method according to claim 4, wherein the creating step includes the steps of:
extracting a unit description from the circuit;
matching the description with the unit description; and
deciding the verification contents.

9. The verification vector creating method according to claim 4, wherein the creating step includes the step of:
altering the functional description on the circuit into a unit description; the step of matching the description with the unit description; and
deciding the verification contents.

10. The verification vector creating method according to claim 5, wherein the creating step creates, on the basis of corresponding information between circuit features prepared beforehand and the verification vector, the verification vector for the circuit features extracted by the step of extracting the featuring circuit.

11. The verification vector creating method according to claim 7, wherein the creating step creates the verification vector on the basis of the corresponding information among the description feature extracted by the step of extracting a featuring description, a prepared description feature and the verification vector.

12. The verification vector creating method according to claim 1, wherein the at least one circuit is layout-described.

13. The verification vector creating method according to claim 12, wherein the creating step includes the step of extracting the transistor level description of the circuit from the layout.

14. The verification vector creating method according to claim 13, wherein the transistor level description of the circuit extracted from the layout contains parasitic element information.

15. The verification vector creating method according to claim 4, wherein the functional description is at least one of Verilog-A and Verilog-AMS descriptions.

16. The verification vector creating method according to claim 5, wherein the featuring circuit means a switch.

17. The verification vector creating method according to claim 5, wherein the featuring description means a switch.

18. A circuit verifying method, comprising the step of:
creating, by using a verification vector creating method according to any of claims 1 to 17, the verification vector of at least one circuit of target circuits; and
verifying the circuit with the verification vector extracted.

19. The circuit verifying method according to claim 18, wherein the verifying step includes the step of:
verifying whether or not at least two circuits are functionally equivalent.

20. The circuit verifying method according to claim 18, wherein the extracting step includes the step of extracting the transistor level description of the circuit from a layout description, and wherein the verifying step includes a circuit verifying step using the verification vector obtained from the transistor level description of the circuit.

21. The circuit verifying method according to claim 20, wherein the transistor level description of the circuit extracted from the layout description contains parasitic information.

22. The circuit verifying method according to any of claims 18 to 21, wherein the creating step includes the steps of:
extracting an input condition for the circuit to come into a specific state; and
extracting a verification vector for the circuit to come into the specific state, from the input condition.

23. The circuit verifying method according to claim 18, wherein the at least one circuit is functionally described, and wherein the method comprises the step of verifying the circuit.

24. The circuit verifying method according to any of claims 18 to 23, wherein the verifying step includes the step of:
comparing the verification results at the verifying step: and
deciding the result on whether or not the characteristics or functions are equivalent to specifications.

25. The circuit verifying method according to claim 24, wherein the decision of the results at the deciding step is based on whether or not the circuit is in the specific state.

26. The circuit verifying method according to any of claims 18 to 23, wherein the verifying step includes the steps of:
creating a combination of input signals; and
deciding whether or not the circuit is in the specific state.

27. The circuit verifying method according to claim 25, wherein the specific state is a power-down state.

28. The circuit verifying method according to claim 18, wherein the verifying step includes the steps of:
creating a test circuit with the verification vector created at the extracting step and the circuit information extracted by the feature extracting means.

29. The circuit verifying method according to claim 18, wherein the verifying step includes the step of creating a test circuit with the verification vector created at the extracting step and the description information extracted by the feature extracting means.
